(19) United States
(12) Patent Application Publication
(10) Pub. No.: US 2021/0132147 A1
(43) Pub. Date: May 6, 2021

(54) TEST PATTERN GENERATING METHOD, TEST PATTERN GENERATING DEVICE AND FAULT MODEL GENERATING METHOD

(71) Applicant: Realtek Semiconductor Corp., HsinChu (TW)

(72) Inventors: Ying-Yen Chen, Hsinchu City (TW); Po-Lin Chen, Hsinchu County (TW); Yin-Ping Chern, Chiayi County (TW)

(21) Appl. No.: 17/073,427

(22) Filed: Oct. 19, 2020

(30) Foreign Application Priority Data
Oct. 31, 2019 (TW) 108139421

(51) Int. Cl. G01R 31/3183; G01R 31/317; G01R 31/28

(52) U.S. Cl. CPC G01R 31/318328; G01R 31/318357; G01R 31/2836; G01R 31/31725; G01R 31/318307

(57) ABSTRACT

A test pattern generating method for generating a test pattern for a circuit under test. The test pattern generating method comprises: (a) computing a plurality of signal delay values which a plurality of cells have due to different defects; (b) comparing the signal delay values and signal path delay information of a target circuit to generate a fault model; and (c) generate at least one test pattern according to the fault model.

### BACKGROUND OF THE INVENTION

### 1. Field of the Invention

The present invention relates to a test pattern generating method, a test pattern generating device and a fault model generating method, and particularly relates to a test pattern generating method, a test pattern generating device and a fault model generating method which can be applied to detect a circuit delay issue.

### 2. Description of the Prior Art

The test of a circuit becomes more and more important in order to ensure the function correctness of the product, since the amount of transistors in circuits have gradually increased functionality while size of chips keep shrinking. A conventional fault model, such as SAF (Stuck At Fault) or TDF (Transition Delay Fault), only models a defect as a fault on the input pins or output pins of a cell. However, the cell interior may also have a defect since the circuit manufacturing process becomes more and more complicated, and the faulty behavior of an interior defect cannot be fully modeled by conventional fault models. Accordingly, related technique field provides a cell aware fault model generating method, which can detect a fault model of a cell interior defect. However, neither the conventional fault model nor the cell aware fault model generating method considers circuit delays when generating test patterns.

### SUMMARY OF THE INVENTION

Therefore, one objective of the present invention is to provide a test pattern generating method and a test pattern generating device, which can generate a test pattern that can test a signal delay problem of the circuit.

Another objective of the present invention is to provide a fault model generating method which can generate a fault model that can show the signal delay problem of the circuit.

One embodiment of the present invention provides a test pattern generating method for generating a test pattern for a circuit. The method comprises: (a) computing a plurality of signal delay values which a plurality of cells have due to different defects; (b) comparing the signal delay values and signal path delay information of a target circuit to generate a fault model; and (c) generate at least one test pattern according to the fault model.

Another embodiment of the present invention provides a fault model generating method for a circuit. The method comprises: (a) computing a plurality of signal delay values which a plurality of cells have due to different defects; and (b) comparing the signal delay values and signal path delay information of a target circuit to generate a fault model.

Still another embodiment of the present invention provides a test pattern generating device for generating a test pattern for a circuit. The device comprises a storage device; and a processing circuit, configured to perform: (a) computing a plurality of signal delay values which a plurality of cells have due to different defects; (b) comparing the signal delay values and signal path delay information of a target circuit stored in the storage device to generate a fault model; and (c) generate at least one test pattern according to the fault model.

In view of above-mentioned embodiment, a test pattern which can test a signal delay problem of the circuit and a fault model which can show the signal delay problem of the circuit can be generated. By this way, the problems of the conventional circuit test method can be improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart illustrating a test pattern generating method according to one embodiment of the present invention.

FIG. 2 is a detail flow chart of the step 101 in FIG. 1 according to one embodiment of the present invention.

FIG. 3 is a detail flow chart of the step 103 in FIG. 1 according to one embodiment of the present invention.

FIG. 4 is a detail flow chart of the step 105 in FIG. 1 according to one embodiment of the present invention.

FIG. 5 is a block diagram illustrating a test pattern generating device according to one embodiment of the present invention.

### DETAILED DESCRIPTION

In following descriptions, a plurality of embodiments are provided to explain the concept of the present invention. Please note, the steps and the sequences thereof are only for examples and do not mean to limit the scope of the present invention.

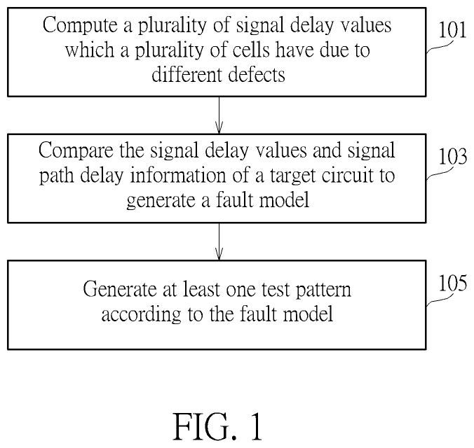

FIG. 1 is a flow chart illustrating a test pattern generating method according to one embodiment of the present invention, which comprises following steps:

Step 101

Compute a plurality of signal delay values which a plurality of cells have due to different defects.

For example, when the cell A has a P defect, the signal delay value is M, and when the cell B has a Q defect, the signal delay value is N. In one embodiment, these signal delay values are made into a signal delay value table for following steps. The cell data library here can be a standard cell library, but it is not limited.

Step 103

Compare the signal delay values and signal path delay information of a target circuit to generate a fault model.

Specifically, the signal delay values in step 101 represent the signal delay values of the cells when it has certain defects. Therefore, after obtaining the cell load or signal path delay information of the target circuit, combined with the signal delay values in step 101, it is possible to know which signal paths may cause signal delays over the acceptable range due to defects. After that, a fault model is generated based on this information. The fault model contains the possible defects of the target circuit and which circuit operations may occur when the target circuit has defects.

Step 105

Generate at least one test pattern according to the fault model.

The test pattern generated in the step 105 can be applied to VLSI (very large scale integration) test, but can be applied to any other kind of test as well. In followings descriptions, examples of detail steps of steps 101, 103, and 105 will be described. However, the followings embodiments are only for examples, other steps which can perform the same function should also fall in the scope of the present invention.

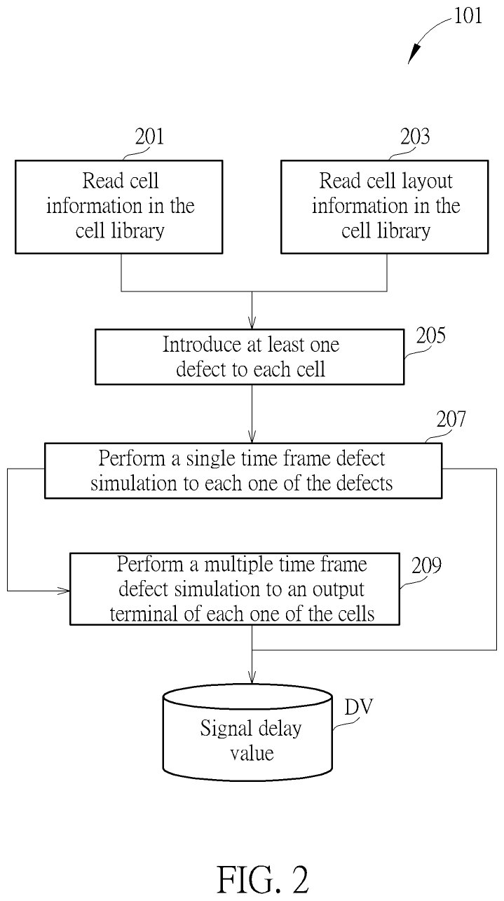

FIG. 2 is a detail flow chart of the step 101 in FIG. 1 according to one embodiment of the present invention, which comprises following steps:

Step 201

Read cell information in the cell library, wherein the cell information comprises cell function or cell timing information of the cell.

Cell function means the type of a cell, for example, the cell is an adder, a flip-flop, or a multiplier. Also, the cell timing information means a time that the cell needs to transmit a signal.

Step 203

Read cell layout information in the cell library. For example, read information such as locations or parameters of at least one resistor, at least one capacitor or at least one metal layer.

Step 205

Introduce at least one defect to each cell. For example, let the cell has at least one following defects: short, open, transistor on, transistor off.

Step 207

Perform a single time frame defect simulation to each one of the defects. “single time frame defect simulation” means giving a constant value to a cell and monitors an output of the cell. For example, give a logic value 1 or 0 to a flip-flop, and monitors an output of the flip-flop.

Step 209

Perform a multiple time frame defect simulation to an output terminal of each one of the cells. “multiple time frame defect simulation” means giving a logic value variation to a cell and monitors an operation of the cell. For example, give a logic value transition from 0 to 1 or 1 to 0 to a flip-flop, and monitors an output of the flip-flop. In one embodiment, a multiple time frame defect simulation is provided respect to various output loads of each cell, to have a more accurate analyzing.

Please note, the embodiment in FIG. 2 is not limited to comprise steps 207 and 209, and may comprise only one of steps 207 and 209. Steps 207 and 209 can be implemented by various simulation software, such as PSPICE or HSPICE. The signal delay value DV in step 101 can be generated by steps 201, 203, 205 and at least one of steps 207 and 209 in FIG. 2. These signal delay values DV can be stored in a storage device for following steps.

In one embodiment, a plurality of first output waves of the devices which have no defect for different signal inputs are respectively recorded, and a plurality of second output waves of the devices which have different defects for different ones of the signal inputs are also respectively recorded. Then, the signal delay values are computed according to differences between the first output waves and the second output waves.

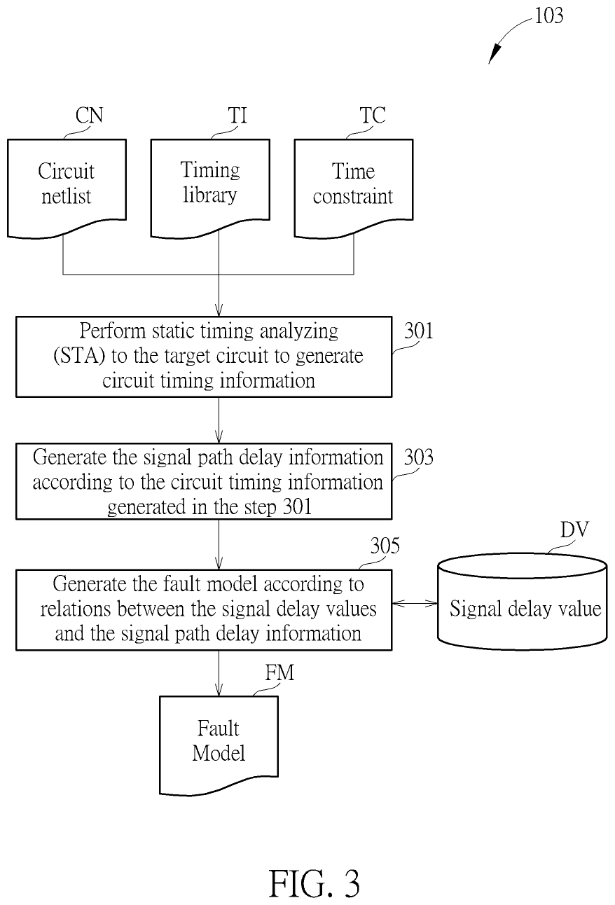

FIG. 3 is a detail flow chart of the step 103 in FIG. 1 according to one embodiment of the present invention, which comprises following steps:

Step 301

Perform static timing analyzing (STA) to the target circuit to generate circuit timing information.

STA is used to analyze the relationship between timings of the circuit to find hidden timing problems. The logic can be optimized or the conditions of the circuit can be restricted based on the results of STA. Static timing tools can be used to identify timing defects, which can include, but are not limited to, whether the setup/hold and restore/remove operations are correct, signal jitter, clock signal width and clock skew, clock signal temporary pulse detection. STA can be performed by a variety of software, such as PrimeTime, SST Velocity, or Blast.

In one embodiment, STA is performed according to a circuit netlist CN, a timing library TI, and time constraint TC. The circuit netlist CN may include but is not limited to: the type of each used cell (which may be called instance), input states and load status of each used cell, and the maximum slack value, the minimum slack value of each used cell. The slack value indicates the difference between the time required by the cell and the time when the signal actually arrives. For example, if a cell needs to be triggered by the positive clock edge at T0, but the positive clock edge reaches at T1, the slack value is T0-T1. Therefore, it can be regarded as the time margin of the signal required by the cell. If the slack value is smaller, the cell is more possible to have an error. The timing library TI may include, but is not limited to: delay values between terminals of a plurality of used cells of a target circuit. The time constraint TC may include, but is not limited to: clock signal information, an expected time for the cell to receive the signal, and a control signal used by the cell. However, persons skilled in the art should understand that STA can be performed based on other data, and such variation should also fall in the scope of the present invention.

Step 303

Generate the signal path delay information according to the circuit timing information generated in the step 301. Additionally, this step can also acquire used cell load (or named instance load) of the target circuit.

Step 305

Generate the fault model according to relations between the signal delay values and the signal path delay information. In one embodiment, the fault model FM is a multiple time frame fault model, but it is not limited. That is, this step will determine whether the specific defect will cause the delay of the target circuit to exceed the acceptable range according to the signal delay values and signal path delay information caused by the cell due to the specific defect, so as to determine whether to make the specific defect contained in a fault list. Afterward, a fault model FM is generated based on the fault list. The above-mentioned specific defect corresponds to a specific fault contained in the fault list, and each specific fault must be tested.

In one embodiment, the signal path delay information includes a slack range of the signal path used by the used cell. Step 305 generates a fault model according to the relationship between the signal delay value and the slack range. For more detail, step 305 determines whether the fault model FM should include the specific defect according to whether the signal delay value caused by the specific defect exceeds the slack range. In one embodiment, the above-mentioned slack range includes a plurality of slack values of a plurality of used signal paths of the used cell. Step 305 generates a fault model FM according to the signal delay value and the relationship between the maximum slack value and the minimum slack value among the plurality of slack values. In one embodiment, when the signal delay value of the used cell due to a specific defect is greater than the maximum slack value (that is, the maximum time margin), it will be considered that the specific defect will cause the circuit to fail, and therefore this specific defect is contained in the fault model FM. However, if the signal delay value of the used cell due to a specific defect is between the maximum slack value and the minimum slack value, it is considered that the specific defect may cause a circuit fault (possible faulty), so the specific error may be included in the fault Model FM, but this specific defect may not be included in the fault model FM according to actual needs. When the signal delay value of the used cell due to the specific defect is lower than the minimum slack value (that is, the minimum time margin), it will be determined that the specific defect will not cause the circuit to fail (fault free), so the specific error will not be contained in the fault model FM.

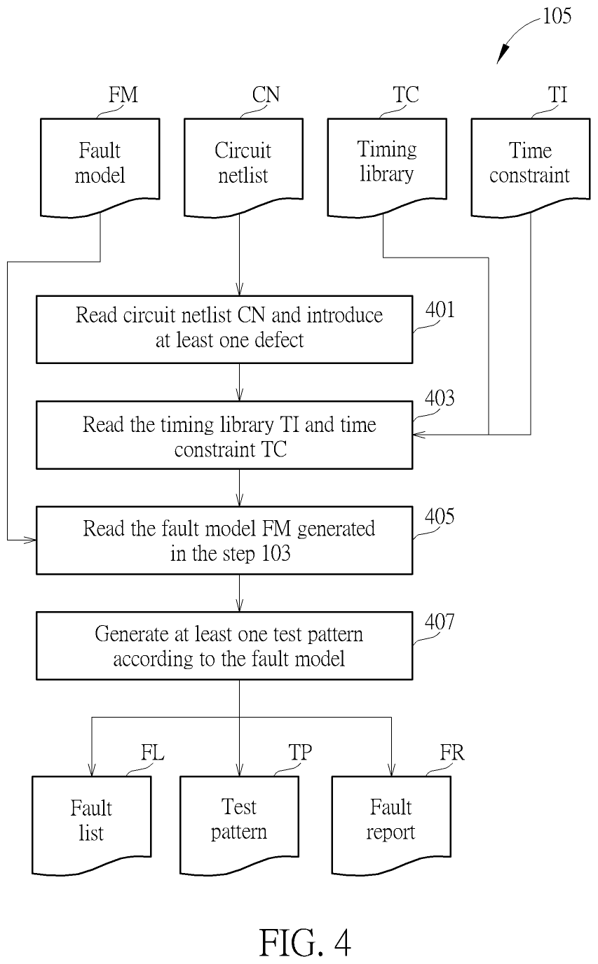

FIG. 4 is a detail flow chart of the step 105 in FIG. 1 according to one embodiment of the present invention, which comprises following steps:

Step 401

Read circuit netlist CN and introduce at least one defect.

Step 403

Read the timing library TI and time constraint TC. Details of the circuit netlist CN, the timing library TI and the time constraint TC are explained in above-mentioned descriptions, thus are omitted for brevity here.

Step 405

Read the fault model FM generated in the step 103.

Step 407

Generate at least one test pattern according to the fault model. In one embodiment, timing aware automatic test pattern generation (timing aware ATPG) is used to generate a test pattern TP according to the fault model. Besides the test pattern TP, the step 407 also generates fault list FL and the fault report FR.

The used cell in the circuit may have multiple signal paths. Therefore, if a shorter signal path is selected, the delay of the signal may not be detected. Thus, an appropriate signal path must be selected for test. The timing aware ATPG can be used to select an appropriate signal path to generate a better test pattern. For example, a plurality of signal paths can be given different weight values to generate a test pattern. Details about the timing aware ATPG are known by persons skilled in the art, for example, the US patent U.S. Pat. No. 8,051,352 has disclosed the relevant content in detail. Therefore, related descriptions are omitted for brevity here.

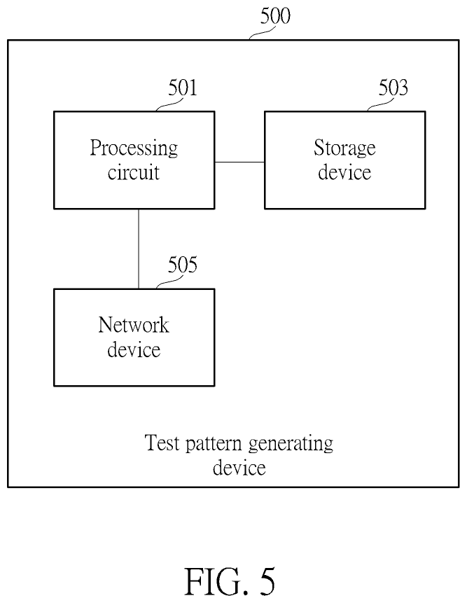

The above-mentioned method can be implemented by different test pattern generating devices. FIG. 5 is a block diagram illustrating a test pattern generating device 500 according to one embodiment of the present invention. As shown in FIG. 5, the test pattern generating device 500 comprises a processing circuit 501 and a storage device 503. The processing circuit 501 is configured to perform the above-mentioned calculations, to read data from the storage device 503, and to control the storage device 503 to store data. In one embodiment, the processing circuit 501 is a microprocessor and the storage device 503 stores at least one program corresponding to the steps in the foregoing embodiments. The processing circuit 501 may execute the program to perform the steps in the foregoing embodiments. The storage device 503 is used to store data required or generated by the foregoing methods, such as a circuit netlist CN, a timing library TI, time constraint TC, a signal delay value DV, or a fault model FM. The storage device 503 may be various types of storage devices, such as an optical disk, a hard disk, ora memory. In addition, the storage device 503 is not limited to be provided in the test pattern generating device 500, and may also be a network hard disk. In this case, the test pattern generating device 500 may further include a network device 505 to connect to the storage device 503. The network device 505 may be a wired network device using optical fiber or the like, or a wireless network device that can be connected to a wireless network (such as WiFi).

In view of above-mentioned embodiment, a test pattern which can test a signal delay problem of the circuit and a fault model which can show the signal delay problem of the circuit can be generated. By this way, the problems of the conventional circuit test method can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A test pattern generating method, for generating a test pattern for a circuit, comprising:
(a) computing a plurality of signal delay values which a plurality of cells have due to different defects;
(b) comparing the signal delay values and signal path delay information of a target circuit to generate a fault model; and
(c) generating at least one test pattern according to the fault model.

2. The test pattern generating method of claim 1, wherein the step (a) comprises:
respectively recording a plurality of first output waves of the devices which have no defect, for different signal inputs;
respectively recording a plurality of second output waves of the devices which have different defects, for different ones of the signal inputs; and
computing the signal delay values according to differences between the first output waves and the second output waves.

3. The test pattern generating method of claim 2, wherein the step (a) further comprises:
reading cell information in a cell library, wherein the cell information comprises cell function or cell timing information of the cell;
reading cell layout information in the cell library;
performing defect simulation according to the cell information or the cell timing information, and the cell layout information to generate the second output waves.

4. The test pattern generating method of claim 2, wherein the step (a) further comprises:
performing a single time frame defect simulation to each one of the defects or performing a multiple time frame defect simulation to an output terminal of each one of the cells.

5. The test pattern generating method of claim 1, wherein the step (b) comprises:
(b1) performing static timing analyzing to the target circuit to generate circuit timing information;
(b2) generating the signal path delay information according to the circuit timing information; and
(b3) generating the fault model according to relations between the signal delay values and the signal path delay information.

6. The test pattern generating method of claim 5, wherein the step (b1) comprises:
receiving a circuit netlist;
receiving a timing library which comprises delay values between terminals of a plurality of used cells of the target circuit;
receiving time constraint; and
performing static timing analyzing to the target circuit according to the circuit netlist, the timing library and the time constraint to generate circuit timing information.

7. The test pattern generating method of claim 6, wherein the signal path delay information comprises slack ranges of the used cells, wherein the step (b3) generates the fault model according to relations between the signal delay values and the slack ranges, wherein the fault model is a multiple time frame fault model.

8. The test pattern generating method of claim 7, wherein the slack range comprises a plurality of slack values of the signal path used by the used cell, wherein the step (b3) generates the fault model according to the signal delay values and a relation between a maximum one and a minimum one of the slack values.

9. The test pattern generating method of claim 1, wherein the step (c) uses a timing aware ATPG to generate a test pattern according to the fault model.

10. A fault model generating method for a circuit, comprising:
(a) computing a plurality of signal delay values which a plurality of cells have due to different defects; and
(b) comparing the signal delay values and signal path delay information of a target circuit to generate a fault model.

11. A test pattern generating device, for generating a test pattern for a circuit, comprising:
a storage device; and
a processing circuit, configured to perform:
(a) computing a plurality of signal delay values which a plurality of cells have due to different defects;
(b) comparing the signal delay values and signal path delay information of a target circuit stored in the storage device to generate a fault model; and
(c) generating at least one test pattern according to the fault model.

12. The test pattern generating device of claim 11, wherein the step (a) comprises:
respectively recording a plurality of first output waves of the devices which have no defect, for different signal inputs;
respectively recording a plurality of second output waves of the devices which have different defects, for different ones of the signal inputs; and
computing the signal delay values according to differences between the first output waves and the second output waves.

13. The test pattern generating device of claim 12, wherein the step (a) further comprises:
reading cell information in a cell library stored in the storage device, wherein the cell information comprises cell function or cell timing information of the cell;
reading cell layout information in the cell library;
performing defect simulation according to the cell information or the cell timing information, and the cell layout information to generate the second output waves.

14. The test pattern generating device of claim 12, wherein the step (a) further comprises:
performing a single time frame defect simulation to each one of the defects or performing a multiple time frame defect simulation to an output terminal of each one of the cells.

15. The test pattern generating device of claim 11, wherein the step (b) comprises:
(b1) performing static timing analyzing to the target circuit to generate circuit timing information;
(b2) generating the signal path delay information according to the circuit timing information; and
(b3) generating the fault model according to relations between the signal delay values and the signal path delay information.

16. The test pattern generating device of claim 15, wherein the step (b1) comprises:
receiving a circuit netlist from the storage device;
receiving a timing library from the storage device, wherein the timing library comprises delay values between terminals of a plurality of used cells of the target circuit;
receiving time constraint from the storage device; and
performing static timing analyzing to the target circuit according to the circuit netlist, the timing library and the time constraint to generate circuit timing information.

17. The test pattern generating device of claim 16, wherein the signal path delay information comprises slack ranges of the used cells, wherein the step (b3) generates the fault model according to relations between the signal delay values and the slack ranges, wherein the fault model is a multiple time frame fault model.

18. The test pattern generating device of claim 17, wherein the slack range comprises a plurality of slack values of the signal path used by the used cell, wherein the step (b3) generates the fault model according to the signal delay values and a relation between a maximum one and a minimum one of the slack values.

19. The test pattern generating device of claim 11, wherein the step (c) uses a timing aware ATPG to generate a test pattern according to the fault model.
